(19) United States
(12) Patent Application Publication
(10) Pub. No.: US 2016/0240575 A1
(43) Pub. Date: Aug. 18, 2016

(54) OPTICAL DEVICE

(71) Applicant: Novatek Microelectronics Corp., Hsinchu (TW)

(72) Inventors: Chin-Hui Huang, Hsinch City (TW); I-Hsiu Chen, Taipei City (TW); Min-Hui Chu, Hsinchu County (TW); Ting-Yung Lin, Hsinchu County (TW)

(21) Appl. No.: 15/016,296

(22) Filed: Feb. 5, 2016

Related U.S. Application Data
(60) Provisional application No. 62/115,646, filed on Feb. 13, 2015.

(51) Int. Cl. H01L 27/146; H01L 31/0232; H01L 31/167; H01L 25/16; F21V 8/00; H01L 31/16

(52) U.S. Cl. CPC H01L 27/14634; G02B 6/0001; H01L 31/162; H01L 31/167; H01L 25/167; H01L 25/165; H01L 31/02327; H01L 27/14629; H01L 27/14625

(57) ABSTRACT

The invention provides an optical device. The optical device includes an image capture unit, at least one light emitting device, and a light conductor. The light conductor defines a space above a substrate on which the image capture unit is disposed. The light conductor includes a central portion and a surrounding portion. The central portion is disposed above the space and has a first surface relatively far from the image capture unit and a second surface opposite to the first surface and relatively close to the image capture unit. The surrounding portion is connected to the central portion and surrounding the space. The surrounding portion includes a reflection surface connected to the first surface and tilted at an angle toward the image capture unit with respect to a plane of the first surface. The reflection surface is adapted to perform total reflection.

### CROSS-REFERENCE TO RELATED APPLICATION

This application claims the priority benefits of U.S. provisional application Ser. No. 62/115,646, filed on Feb. 13, 2015. The entirety of the above-mentioned patent application is hereby incorporated by reference herein and made a part of this specification.

### BACKGROUND OF THE INVENTION

1. Field of the Invention

The invention relates generally to an optical device.

2. Description of Related Art

Optical devices such as optical fingerprint collection devices are widely used for fingerprint collection and identification. The collection of fingerprints through optical devices is based on optical imaging the finger surface through optical sensors. Most conventional optical devices for fingerprint collection use a prism which is directly contacted by a finger of the user, and a light source and an image capture unit is installed at different side of the prism. Through total internal reflection and frustrated total internal reflection (FTIR), the ridge-valley patterns of a fingerprint may produce a high contrast fingerprint image.

However, through the use of a prism, the volume of the optical device is relatively large. In particular, the thickness of the optical device must be greater than the height of the prism. Since the prism must be large enough to contact an entire finger, the overall volume required of the prism limits how small the height of the prism may be. Therefore, since the thickness of the optical fingerprint collection device is limited to be greater than the height of the prism, the resulting overall volume of the optical device is relatively large. As a result, the optical device cannot be conveniently installed in electronic devices where installation space is limited.

Electronic devices have been trending to be slim. Installing a conventional large optical device will result in the electronic device unable to be thin.

### SUMMARY OF THE INVENTION

The invention provides an optical device. The optical device includes an image capture unit, at least one light emitting device, and a light conductor. The light conductor defines a space above a substrate on which the image capture unit is disposed. The light conductor includes a central portion and a surrounding portion. The central portion is disposed above the space and has a first surface relatively far from the image capture unit and a second surface opposite to the first surface and relatively close to the image capture unit. The surrounding portion is connected to the central portion and surrounding the space. The surrounding portion includes a reflection surface connected to the first surface and tilted at an angle toward the image capture unit with respect to a plane of the first surface. The reflection surface is adapted to perform total reflection.

According to an embodiment of the invention, the surrounding portion includes an inner surrounding surface enclosing the space, connected to the second surface of the central portion, and an outer surrounding surface being the reflection surface.

According to an embodiment of the invention, the surrounding portion includes an inner surrounding surface enclosing the space, connected to the second surface of the central portion, and an outer surrounding surface having at least two surfaces forming an obtuse angle. One of the at least two surfaces is the reflection surface.

According to an embodiment of the invention, the surrounding portion includes an inner surrounding surface enclosing the space and having at least two surfaces forming an obtuse angle. One of the at least two surfaces is connected to the second surface of the central portion. The surrounding portion also includes an outer surrounding surface having at least two surfaces forming an obtuse angle, wherein one of the at least two surfaces is the reflection surface.

According to an embodiment of the invention, the reflection surface is adapted to totally reflect light beams emitted from the at least one light emitting device to the first surface of the central portion.

According to an embodiment of the invention, the reflection surface is tilted toward the image capture unit so as to form an obtuse angle with respect to the first surface.

According to an embodiment of the invention, the surrounding portion of the light conductor defines at least one containing space adapted to enclose the at least one light emitting device.

According to an embodiment of the invention, the surrounding portion of the light conductor further includes a surface being an incident surface for the light beams from the at least one light emitting device.

According to an embodiment of the invention, the reflection surface is coated with metal so as to totally reflect the light beams.

According to an embodiment of the invention, the surrounding portion includes an inner surrounding surface enclosing the space and connected to the second surface of the central portion, and the inner surrounding surface is coated with metal so as to totally reflect the light beams.

According to an embodiment of the invention, the image capture unit is configured to capture an image of an object by receiving scattered light beams when total internal reflection at the first surface is frustrated by the object touching the optical device.

According to an embodiment of the invention, the light conductor is light pervious to the light beam.

According to an embodiment of the invention, the optical device further includes a microstructure layer. The microstructure layer is disposed on the first surface. The microstructure layer is adapted to scatter light beams.

Based on the above, the light conductor surrounds the image capture unit, and reflects the light beam within the light conductor. Since the light conductor is thin, the optical device may be relatively thin, allowing convenient installation in devices with limited installation space.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 is a three-dimensional schematic view of an optical device according to an embodiment of the invention.

FIG. 2 is a bottom view of the optical device of FIG. 1.

FIG. 3 is a schematic cross-sectional view of the optical device of FIG. 1 taken along the line A-A′.

FIG. 4 is the schematic cross-sectional view of the optical device of FIG. 3 contacting a finger.

FIG. 5 is a three-dimensional schematic view of an optical device according to an embodiment of the invention.

FIG. 6 is a bottom view of the optical device of FIG. 5.

FIG. 7 is a schematic cross-sectional view of the optical device of FIG. 5 taken along the line B-B′.

FIG. 8 is a schematic cross-sectional view of an optical device according to yet another embodiment of the invention.

FIG. 9 is a schematic cross-sectional view of an optical device according to yet another embodiment of the invention.

FIG. 10 is a schematic cross-sectional view of an optical device according to yet another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

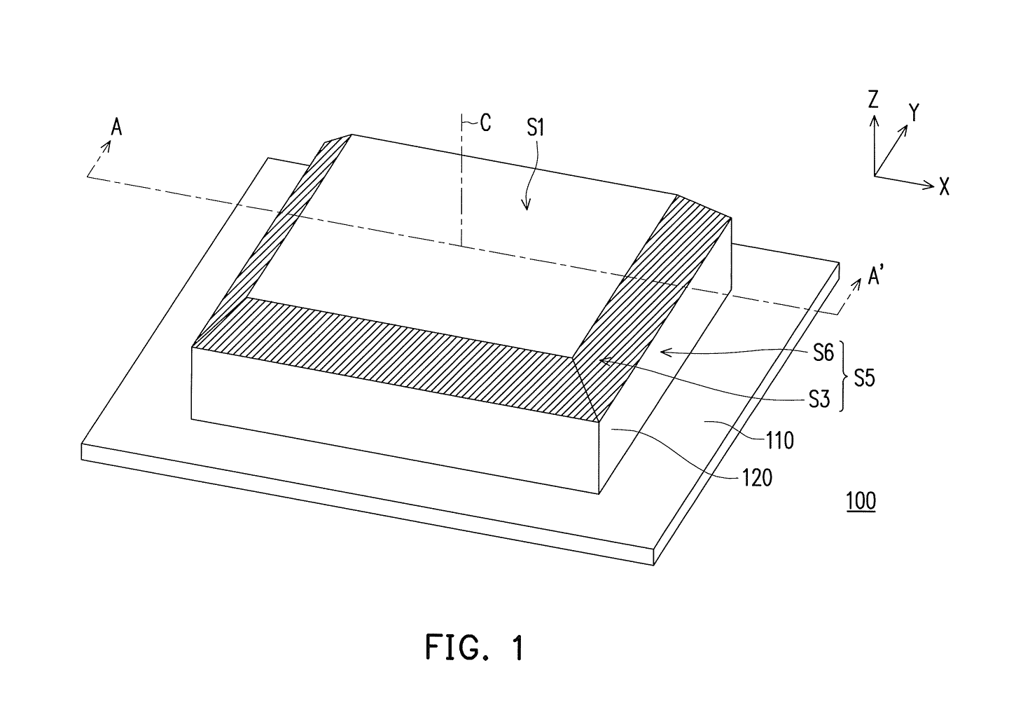

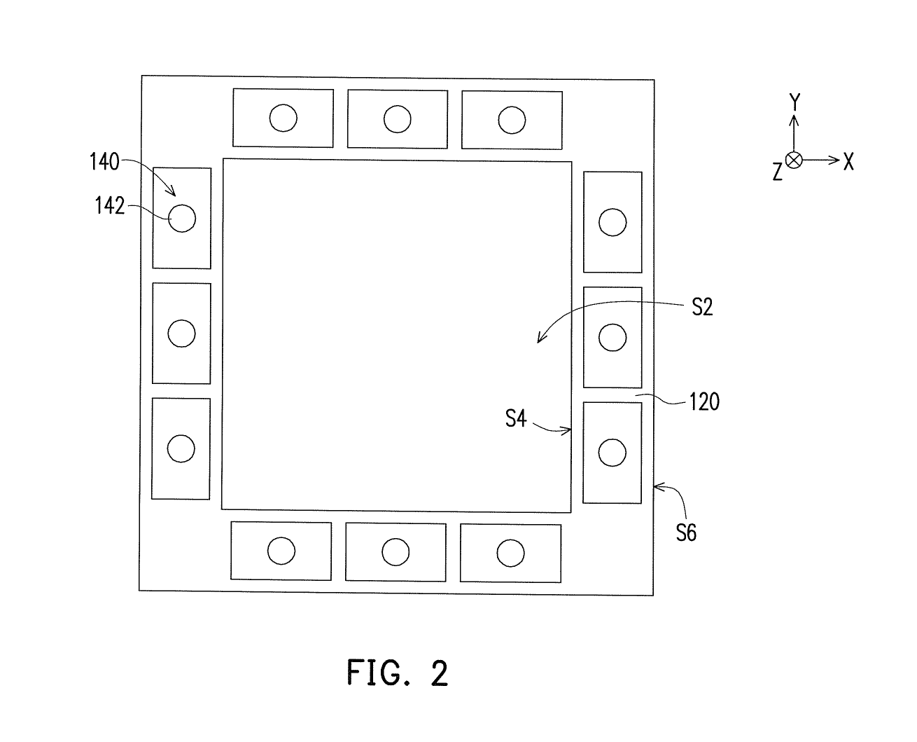

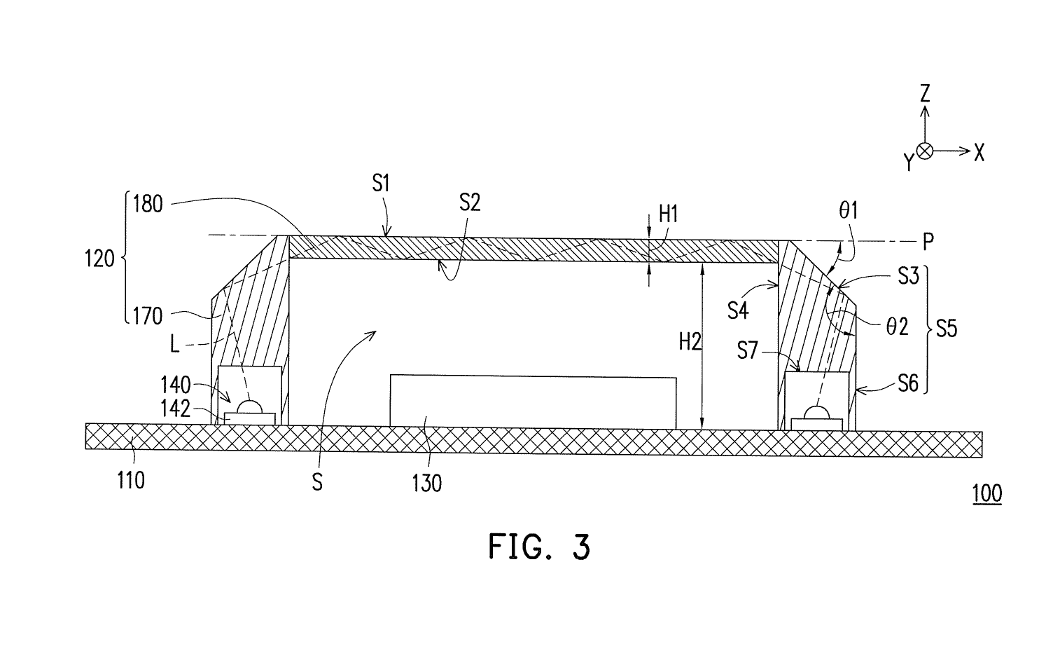

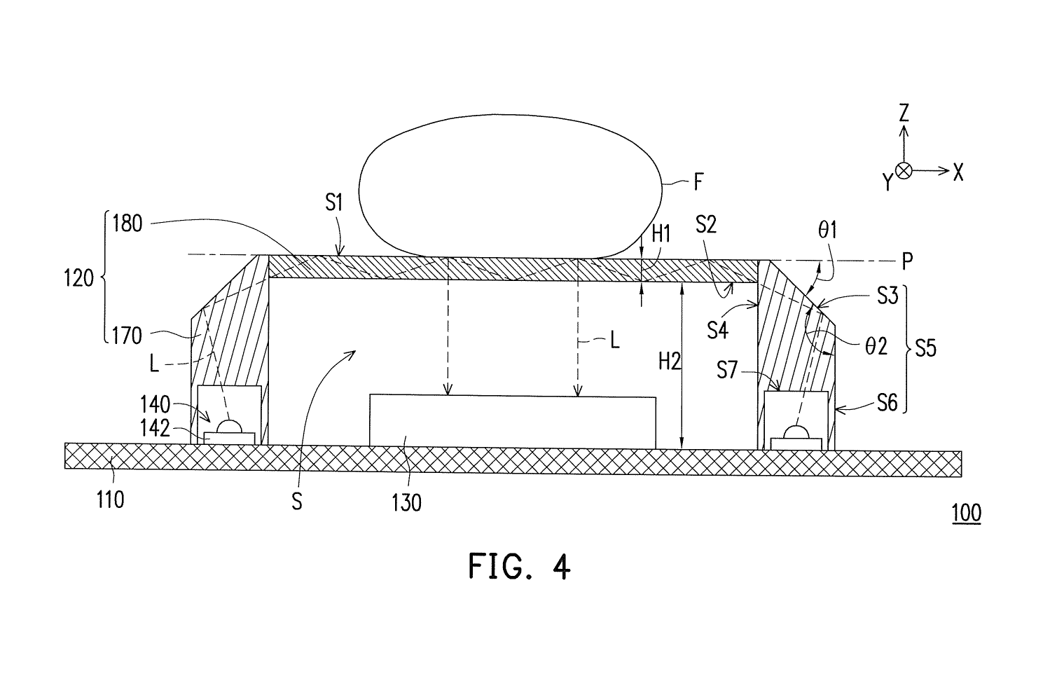

FIG. 1 is a three-dimensional schematic view of an optical device according to an embodiment of the invention. FIG. 2 is a bottom view of the optical device of FIG. 1. FIG. 3 is a schematic cross-sectional view of the optical device of FIG. 1 taken along the line A-A′. FIG. 4 is the schematic cross-sectional view of the optical device of FIG. 3 contacting a finger. Referring to FIG. 1 to FIG. 4, an optical device 100 includes an image capture unit 130, at least one light emitting device 142, and a light conductor 120. The light conductor 120 defines a space S above a substrate 110 on which the image capture unit 130 is disposed. The light conductor 120 includes a central portion 180 and a surrounding portion 170. The central portion 180 is disposed above the space S and includes a first surface S1 relatively far from the image capture unit 130 and a second surface S2 opposite to the first surface S1 and relatively close to the image capture unit 130. That is to say, relative to the first surface S1, the second surface S2 is closer to the image capture unit 130. The surrounding portion 170 is connected to the central portion 180 and surrounds the space S. The surrounding portion 170 includes an inner surrounding surface S4 enclosing the space S and an outer surrounding surface S5. The outer surrounding surface S5 includes at least two surfaces, a reflection surface S3 and an outer surface S6. The reflection surface S3 is connected to the first surface S1 and tilted at an angle θ₁ toward the image capture unit 130 with respect to a plane P of the first surface S1. The reflection surface S3 is adapted to perform total reflection. The reflection surface S3 and the outer surface S6 form an obtuse angle θ₂, and the reflection surface S3 also forms an obtuse angle with respect to the first surface S1. The outer surface S6 may be substantially perpendicular to the substrate 110. The inner surrounding surface S4 is connected to the second surface S2 of the central portion 180. The angle at which the inner surrounding surface S4 is connected to the second surface S2 may be substantially perpendicular. That is to say, the cross-sectional shape of the space S that is defined by the light conductor 120 may be, for example, a rectangle. The three-dimensional shape of the space S is, for example, a cuboid. However, the invention is not limited thereto, and the angle may be adjusted according to design requirements and the shape of the space S may be different, and the three dimensional shape of the space S may be, for example, a dome, a trapezoidal prism, or any other suitable shape.

The surrounding portion 170 further includes at least one surface S7 enclosing the at least one light emitting device 142. That is to say, the surrounding portion 170 defines at least one containing space 140 with the substrate 110. The containing space 140 is defined by the at least one surface S7 and the substrate 110. The containing space 140 is adapted to enclose the light emitting device 142. The surface S7 is adapted to be an incident surface for the light beams from the at least one light emitting device 142 to enter the light conductor 120.

In the embodiment, two containing spaces 140 are shown in FIG. 3, and the containing space 140 has a square shaped cross-section. However, the invention is not limited thereto. The number of containing spaces 140 and number of light sources 142 can be adjusted according to user requirements. Furthermore, the cross-section of the containing space 140 can be any suitable shape such as a dome or a rectangle. In addition, the containing space 140 can also be shaped to closely fit and contact around the light source 142 so that the surface S7 which is the incident surface is in contact with the light source 142.

The light emitting device 142 is disposed on the substrate 110 and emits a plurality of light beams. The reflection surface S3 is adapted to reflect or totally reflect light beams emitted from the at least one light emitting device 142 to the first surface S1 of the central portion 180. For example, the light beam L is reflected or totally reflected by the reflection surface S3 to the first surface S1 of the central portion 180. Thus, the reflection surface S3 may be a total reflection surface adapted to totally reflect the light beam L within the light conductor 120. The reflection surface S3 is tilted at the angle θ₁ toward the image capture unit 130 with respect to a plane P of the first surface S1. In the embodiment, the plane P of the first surface is parallel to an x-axis direction. This way, the light beam L may be totally reflected within the light conductor 120 as the total internal reflection, which is also called total reflection. The angle θ₁ is less than 90 degrees, and for example, between 40 degrees and 50 degrees such that the reflection surface S3 is configured to be a surface where a total reflection occurs. However, the invention is not limited thereto. It should be noted that the light beams emitted from the light emitting device 142 can also be light beams that are not ideally parallel. The configuration of the angle θ₁ (or the configuration of an angle formed by the reflection surface S3 and the first surface S1 is for totally reflecting most of the incident light beams having different light paths to the first surface S1 after traveling to the reflection surface S3 (at the same time, a small portion of the incident light beams may be reflected to the first surface S1 and refracted to outside the optical device). Or, the configuration of the angle θ₁ may not cause almost all of the light beams to be totally reflected to the first surface S1, but the proportion of the light beams that are totally reflected to the first surface S1 may be greater than the proportion of the refracted light beams escaped from the optical device. The angle θ₁ can be adjusted according to the user requirements. The reflection surface S3 may be coated with metal so as to increase the proportion of light beams emitted from the light emitting device 142 to be reflected off the reflection surface S3 to the central portion 180 of the light conductor 120. This increases the amount of light within the light conductor 120, so as to increase the brightness and contrast of the image captured by the image capture unit 130.

In the embodiment, a thickness H1 (i.e., the thickness of the central portion 180) between the first surface S1 and the second surface S2 is, for example, between 0.2 mm and 0.8 mm. However, the invention is not limited there to. The thickness H1 provided between the first surface S1 and the second surface S2 is likely desired to be as thin as possible so as to keep the optical device 100 thin. However, a greater thickness allows more light beams from the light emitting device 142 to enter the central portion 180 between the first surface S1 and the second surface S2. In addition, the thickness H1 must be thick enough so that when a user presses the first surface S1, the light conductor 120 does not break. Therefore, the thickness H1 between the first surface S1 and the second surface S2 may be adjusted according to user requirements.

In the embodiment, the material usually surrounding the light conductor 120 is air. In detail, the space between the light conductor 120 and the image capture unit 130 is usually air. When the optical device 100 is not contacted, everything outside the first surface S1 is usually air. The refractive index of air is around 1. In the embodiment, the refractive index of the material of the light conductor 120 is, for example, from 1.4 to 2 for glass, 1.49 for polymethylmethacrylate (PMMA), 1.58 for polycarbonate (PC), 1.65 for resin, or 1.77 for sapphire. However, the invention is not limited thereto. The light conductor 120 is also light pervious to the light beam L. That is to say, the light beams emitted from the light emitting device 142 are capable of passing through the light conductor 120. When the first surface S1 is not contacted by a finger, the material outside the first surface S1 is air. At this point, the light emitted from the light emitting device 142 is reflected or totally reflected by the reflection surface S3 to the first surface S1 and total internal reflection may occur in the light conductor 120. In detail, after the light is totally reflected from the first surface S1 to the second surface S2, the light may be totally reflected from the second surface S2 to the first surface S1. That is to say, the light will be totally reflected between the second surface S2 and the first surface S1. On the other hand, light may have incident angles that do not cause total internal reflection at the first surface S1 and the second surface S2, and may be refracted at the first surface S1 to outside of the optical device 100. Or, the light may be, for example, reflected from the first surface S1 and refracted at the second surface S2 to then enter the image capture unit 130.

When the light travels to a boundary of two different mediums, for example, the light is incident from a medium of a greater refraction index to another medium of a smaller refraction index, there is more reflection and less refraction. For example, compared to the refraction index of the air (approximate to 1), the refraction index of a human finger is larger and closer to the refraction index of the light conductor 120. Hence, there is more reflection light when the light travelling in the light conductor 120 to a boundary of the light conductor 120 and the air than to a boundary of the light conductor 120 and another medium which has a refraction index larger than the air has. Referring to FIG. 4, when the first surface S1 is not contacted by a finger, most of the light beams entering the central portion 180 of the light conductor 120 may have total internal reflection between the first surface S1 and the second surface S2 (only a small portion of the light is refracted and escaped out of the optical device or to the image capture unit 130). When the finger F contacts the first surface S1, part of the light beam L in the contact portion (i.e. the ridges of the finger) is reflected and the other part of the light beam L in the contact portion is refracted. The part of the light beam L refracted and entering to the finger F is some absorbed by the finger and some scattered. Due to the refraction light entering the finger, the light energy reflected to the image capture unit 130 remains less. On the other hand, the valleys of the finger F do not substantially contact the first surface S1. Thus, there is an air gap between the valley of the finger F and the first surface S1. As a result, the valley positions may have total internal reflection and reflection, and the reflected light energy is more than in the ridge portion. Thus, the valley portions have more light to be reflected to the second surface S2 then be refracted to enter the image capture unit 130. The image capture unit 130 may then, for example, generate a fingerprint image having darker ridge portions and brighter valley portions. In the embodiment, the object that contacts the first surface S1 of the optical device 100 is a finger F. The image of the object is the fingerprint of the finger F. However, the invention is not limited thereto. The object may be any object other than a finger F, and the image may be any image of any suitable object contacting the first surface S1.

Furthermore, the inner surrounding surface S4 may be coated with metal so as to further increase the amount of light beams reflected to the central portion 180 of the light conductor 120. As the amount of light beams reflected to the central portion 180 of the light conductor 120 is increased, the image capture unit 130 receives more light and generates a relatively clear image. In addition, the outer surface S6 and the reflection surface S3 of the outer surrounding surface S5 may also be coated with metal so as to further increase the amount of light beams reflected to the central portion 180 of the light conductor 120.

Furthermore, in the embodiment, the central portion 180 may be scratch resistant material as shown in FIG. 3. That is to say, the material of the central portion 180 may be a suitable scratch resistant material. In the embodiment, the central portion 180 and the surrounding portion 170 are separately formed in order to include the scratch resistant material as the material of the central portion 180. This way, the light conductor 120 is protected from being scratched. The scratch resistant material is, for example, sapphire, but the invention is not limited thereto. The scratch resistant material that is used can be selected according to user requirements. The light beam L will still transmit through the scratch resistant material to the central portion 180 formed by the scratch resistant material. When the finger F contacts the first surface S1, part of the light beam L in the ridge portion is reflected and the other part is refracted. The part of the light beam L that is refracted and enters to the finger F are some absorbed by the finger and some scattered. Due to the refraction light entering the finger, the light energy reflected to the image capture unit 130 remains less. Regarding the valley portions that do not substantially contact the first surface S1, the light beam L may have total internal reflection and reflection at the valley positions, and the reflected light is more than in the ridge portion. The reflected light in the valley portion is refracted from the second surface S2 to reach the image capture unit 130. Thus, the image capture unit 130 receives the light beams so as to generate a fingerprint image including darker ridge portions and brighter valley portions. FIG. 3 and FIG. 4 show the material of the central portion 180 as a scratch resistant material different from the material of the surrounding portion 170. This clearly shows the distinction between the central portion 180 and the surrounding portion 170. However, the invention is not limited thereto. The material of the central portion 180 is not limited to a scratch resistant material, and may be the same material as the surrounding portion 170. In addition, the surrounding portion 170 may also be composed of the same scratch resistant material as the central portion 180. That is to say, the material of the central portion 180 and the surrounding portion 170 may be the same or different, and may be scratch resistant or not scratch resistant according to user requirements. In the embodiment, a height H2 from the substrate to the second surface S2 of the central portion 180 is greater than a height of the image capture unit 130 and a lens (not shown).

FIG. 2 is a bottom view of the optical device of FIG. 1. Referring to FIG. 2, FIG. 2 shows the bottom view of the optical device 100 without showing the substrate 110 and the image capture unit 130. FIG. 2 shows the arrangement of the light emitting devices 142 and the containing spaces 140. In the embodiment, the number of light emitting devices 142 is twelve. However, the invention is not limited thereto. The number of light emitting devices 142 and the number of the containing spaces 140 may be adjusted according to the user. In addition, the spacing and arrangement of the light emitting devices 142 on each of the sides of the light conductor 120 may be adjusted according to the user. In the embodiment, the light emitting devices 142 are light emitting diodes. However, the invention is not limited thereto.

As seen in FIG. 2, the number of containing spaces 140 is equal to the number of light emitting devices 142. However, the invention is not limited thereto. In another embodiment, the light conductor 120 may include only one containing space 140 extending through all sides of the light conductor 120. That one containing space 140 may contain all the light emitting devices 142 of the optical device 100. The number of containing spaces 140 may be adjusted according to design requirements.

FIG. 1 is a three-dimensional schematic view of the optical device. In the embodiment, the light conductor 120 is rotatably symmetrical about a center axis C of the first surface S1 of the light conductor 120, such as the light conductor 120 having a square shape depicted in FIG. 2, which has a rotational symmetry of 90 degrees. However, the invention is not limited thereto, and the light conductor can be any shape with or without rotational symmetry.

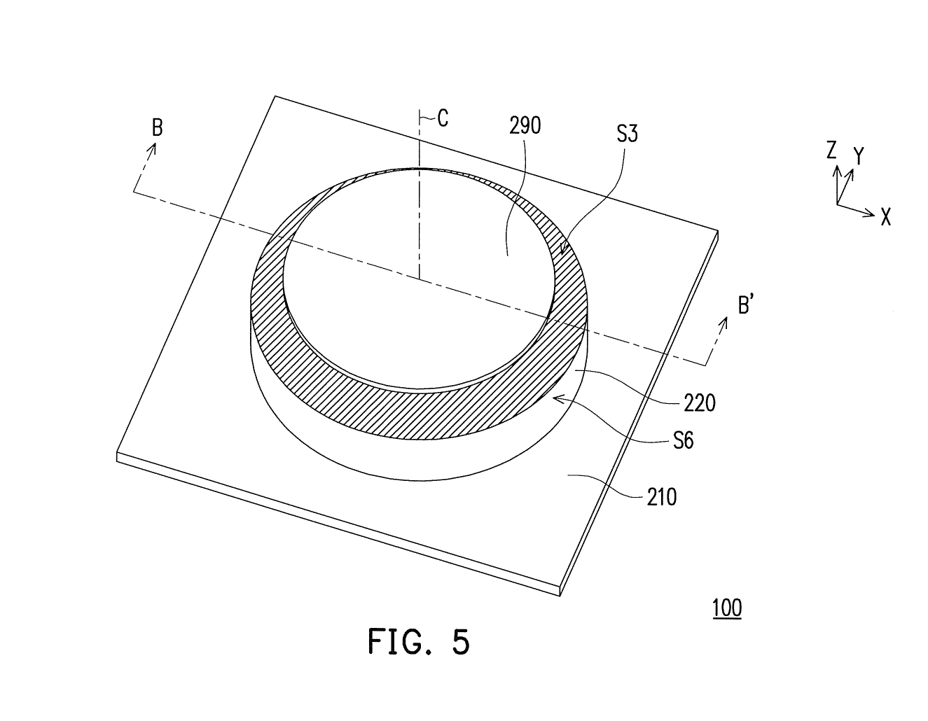

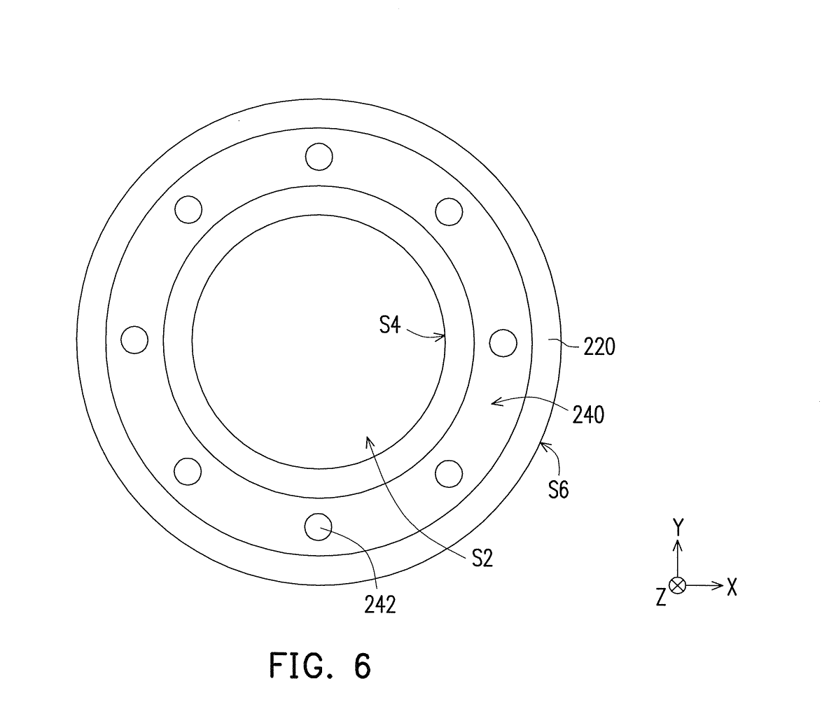

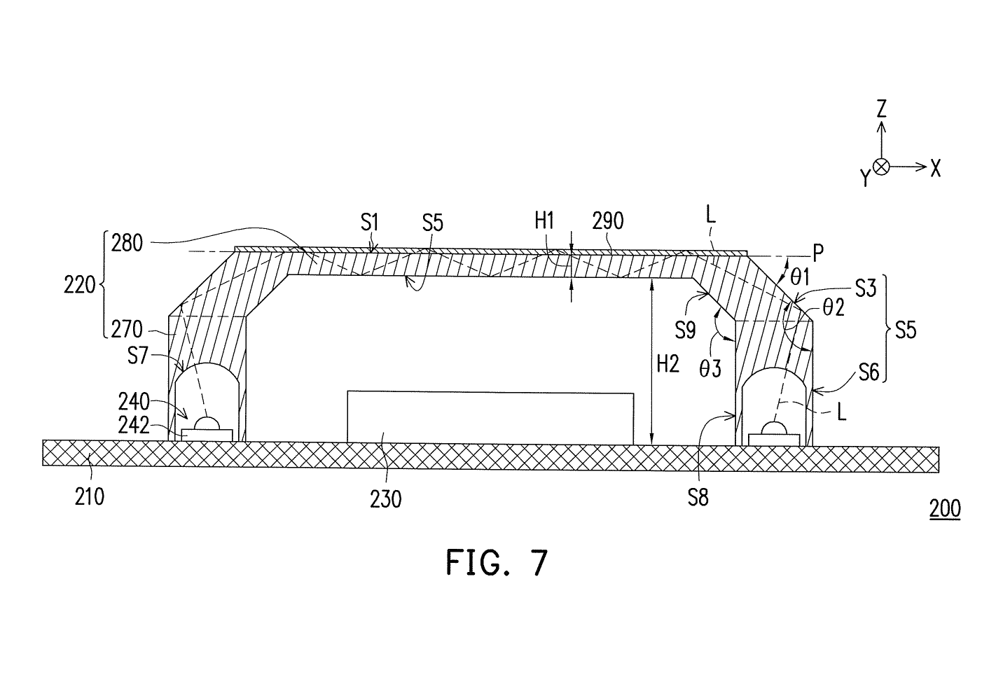

FIG. 5 is a three-dimensional schematic view of an optical device according to an embodiment of the invention. FIG. 6 is a bottom view of the optical device of FIG. 5. FIG. 7 is a schematic cross-sectional view of the optical device of FIG. 5 taken along the line B-B′. Referring to FIG. 5 to FIG. 7, the embodiment of FIG. 5 to FIG. 7 is similar to the embodiment of FIG. 1 to FIG. 4. Similar elements will apply similar reference numerals as in the embodiment of FIG. 1 to FIG. 4. Description of similar elements will not be repeated and can be referred to in the description of FIG. 1 to FIG. 4. As seen in FIG. 7, the optical device 200 includes a substrate 210, a light emitting device 242, a light conductor 220, and an image capture unit 230. The light conductor 220 includes a central portion 280 and a surrounding portion 270. A containing space 240 is defined by a surface S7, which is the incident surface for the light beams from the light emitting device 242, of the surrounding portion 270 and the substrate 210. The optical device 200 further includes a scratch resistant layer 290 disposed on the first surface S1 of the central portion 280 for protecting the light conductor 220 from being scratched. A material of the scratch resistant layer 290 is, for example, sapphire. The scratch resistant layer 290 can also use any other kind of scratch resistant material. When the finger F (ridge portions) contacts the scratch resistant layer 290, the light beam L will transmit through the central portion 280 and the scratch resistant layer 290 to the finger F. A portion of the light entering to the finger F is absorbed and scattered, and only a little light energy can be reflected to the image capture unit 230. On the other hand, the valley positions may have more reflected light than the ridge portions and the light is reflected to the second surface S2 then to the image capture unit 230. Furthermore, a cross-sectional shape of the containing space 240 has a dome shape. However, the cross-sectional shape of the containing space 240 may be any other suitable shape such as a square or a rectangle. In addition, the containing space 240 can also be shaped to closely fit and contact around the light source 242 so that the light incident surface S7 is in contact with the light source 242.

Furthermore, in the embodiment shown in FIG. 7, the surrounding portion 270 includes an inner surrounding surface having at least two surfaces S8, S9 that form an obtuse angle θ₃. In the embodiment, the surface S9 is connected to the second surface S2 of the central portion 280. That is to say, in the embodiment, the cross-sectional shape of the space S is a combination of a trapezoid and a rectangle. The description of the thicknesses and heights of the optical device 200 may be referred to in the description of FIG. 1 to FIG. 4, and will not be repeated herein. In addition, the arrangement of the light emitting devices 242 and the containing spaces 240 may be referred to the description of FIG. 1 to FIG. 4, as the number and configuration may be adjusted according to user requirements.

Referring to FIG. 5, in the embodiment, the light conductor 220 is rotatably symmetrical about a center axis C of the first surface S1 of the light conductor 220. In particular, the light conductor 220 has a cylindrical shape, and has a rotational symmetry of 360 degrees. In other embodiments, the shape of the light conductor 220 can be, for example, square shaped with a rotational symmetry of 90 degrees similar to FIG. 1 and FIG. 2, or rectangular shaped with a rotational symmetry of 180 degrees. However, the invention is not limited thereto, and the light conductor can be any shape with or without rotational symmetry.

Referring to FIG. 6, FIG. 6 shows the bottom view of the optical device 200 without showing the substrate 210 and the image capture unit 230 of FIG. 7. FIG. 6 shows the arrangement of the light emitting devices 242 and the containing spaces 240. In the embodiment, the number of light emitting devices 242 is eight. However, the invention is not limited thereto. The number of light emitting devices 242 and the number of and the containing spaces 240 may be adjusted according to the user. In addition, the spacing and arrangement of the light emitting devices 242 on around the light conductor 220 may be adjusted according to the user. In the embodiment, the light emitting devices 242 are light emitting diodes. However, the invention is not limited thereto.

As seen in FIG. 6, the number of containing spaces 240 is one, and all the light emitting devices 242 are contained in the containing space 240. However, the invention is not limited thereto. The containing spaces 240 may be increased and adjusted in size to contain one or more light emitting devices 242. Similar to FIG. 3, the number of containing spaces 240 may also be the same number as the light emitting devices 242. The number of containing spaces 240 may be adjusted according to design requirements.

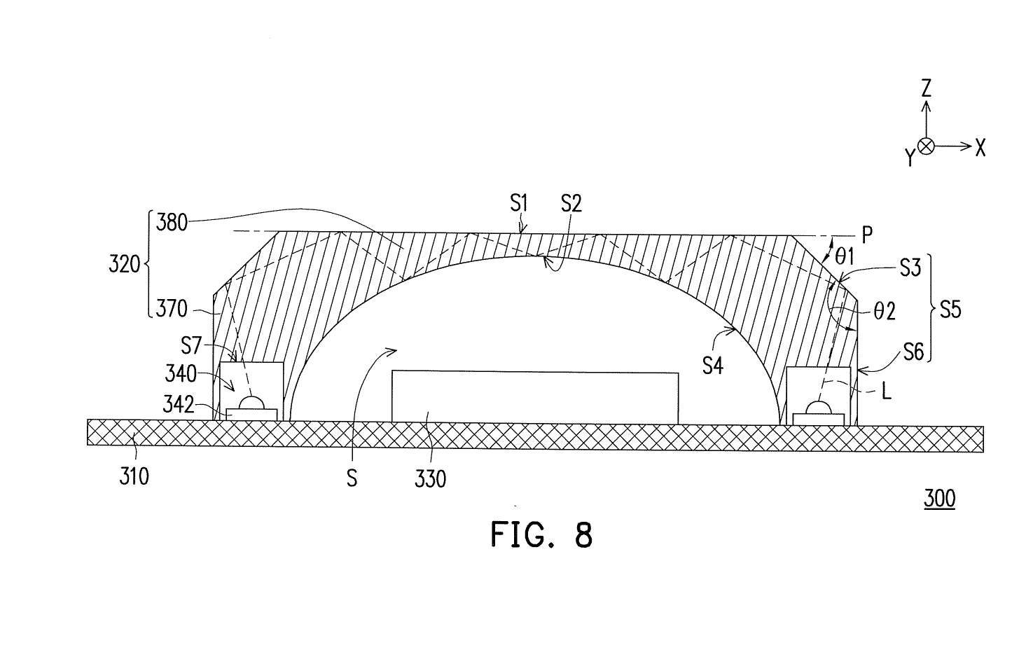

FIG. 8 is a schematic cross-sectional view of an optical device according to yet another embodiment of the invention. Referring to FIG. 8, the embodiment of FIG. 8 is similar to the embodiment of FIG. 1. Similar elements will apply similar reference numerals as in the embodiment of FIG. 1. Description of similar elements will not be repeated and can be referred to in the description of FIG. 1. As seen in FIG. 8, the optical device 300 includes a substrate 310, a light emitting device 342, a light conductor 320, and an image capture unit 330. The light conductor 320 includes a central portion 380 and a surrounding portion 370 connected to each other. A containing space 340 is defined by a surface S7 of the surrounding portion 370 and the substrate 310. The description of the cross-sectional shape of the containing space 340 is similar to the containing space 140, and the same description will not be repeated herein.

Furthermore, in the embodiment, the surrounding portion 370 includes the inner surrounding surface S4 connected to the second surface S2 of the central portion 380 to define the space S. In the embodiment, the cross-sectional shape of the space S is defined as a dome. That is to say, the connection between the inner surrounding surface S4 and the second surface S2 form a dome shape to define the cross section of the space S. The three-dimensional shapes of the light conductor 320 may be similar to the three-dimensional shape as shown in FIG. 1 or FIG. 5, but is not limited thereto. That is to say, the light conductor 320 may have different types of rotational symmetry or not. The three-dimensional shape of the light conductor 320 may be any suitable shape according to design requirements.

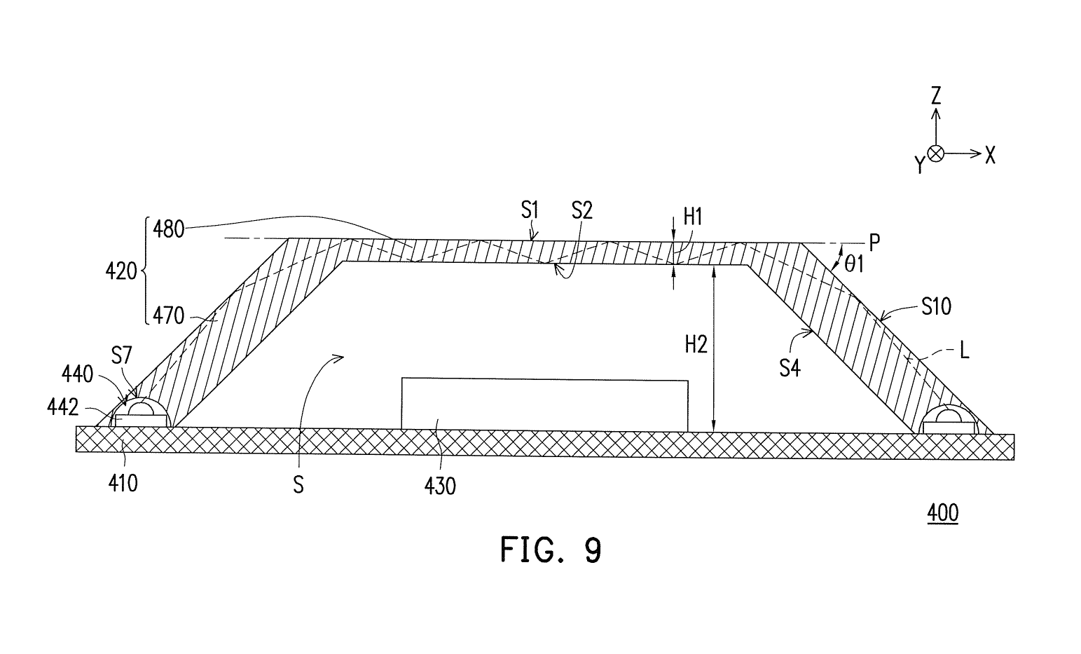

FIG. 9 is a schematic cross-sectional view of an optical device according to yet another embodiment of the invention. Referring to FIG. 9, the embodiment of FIG. 9 is similar to the embodiment of FIG. 1. Similar elements will apply similar reference numerals as in the embodiment of FIG. 1. Description of similar elements will not be repeated and can be referred to in the description of FIG. 1. As seen in FIG. 9, the optical device 400 includes a substrate 410, a light emitting device 442, a light conductor 420, and an image capture unit 430. The light conductor 420 and the substrate 410 define a space S. The light conductor 420 includes a central portion 480 and a surrounding portion 470 connected to each other.

Furthermore, in the embodiment, the surrounding portion 470 includes the inner surrounding surface S4 connected to the second surface S2 of the central portion 480. The surrounding portion 470 also includes an outer surrounding surface S10 connected to the first surface S1 of the central portion. In the embodiment, the outer surrounding surface S10 is tilted towards the image capture unit 430 to form an angle θ₁ with the substrate 410. Similarly, the inner surrounding surface S4 tilts towards the image capture unit 430 to form an angle with the substrate. In the embodiment, the inner surrounding surface S4 and the outer surrounding surface S10 are parallel to each other so that the respective angles formed by the inner surrounding surface S4 and the outer surrounding surface S10 are equal to each other. However, the invention is not limited thereto, and the inner surrounding surface S4 and the outer surrounding surface S10 do not have to be parallel to each other. Furthermore, the outer surrounding surface S10 is the reflection surface adapted to totally internally reflect the light beam L.

A containing space 440 is defined by a surface S7 of the surrounding portion 470 and the substrate 410. The description of the cross-sectional shape of the containing space 440 is similar to the containing space 240, and the same description will not be repeated herein.

In the embodiment, the shape of the cross section of the space S is defined as a trapezoid. That is to say, the connection between the inner surrounding surface S4 and the second surface S2 form a trapezoid shape to define the cross section of the space S. The three-dimensional shapes of the light conductor 420 may be similar to the three-dimensional shape as shown in FIG. 1 or FIG. 5, but is not limited thereto. The three-dimensional shape of the light conductor 420 may be any suitable shape according to design requirements. The three-dimensional shapes of the light conductor 420 may be similar to the three-dimensional shape as shown in FIG. 4 or FIG. 6, but is not limited thereto. That is to say, the light conductor 420 may have different types of rotational symmetry or not. The three-dimensional shape of the light conductor 420 may be any suitable shape according to design requirements.

In the embodiment of FIG. 8 and FIG. 9, part of the light beam L is reflected and the other part of the light beam L is refracted when the optical device is touched, so that the image capture unit may capture an image of an object by receiving reflected and refracted light beams. The same descriptions can be referred to in the description of FIG. 1 to FIG. 4, and will not be repeated herein.

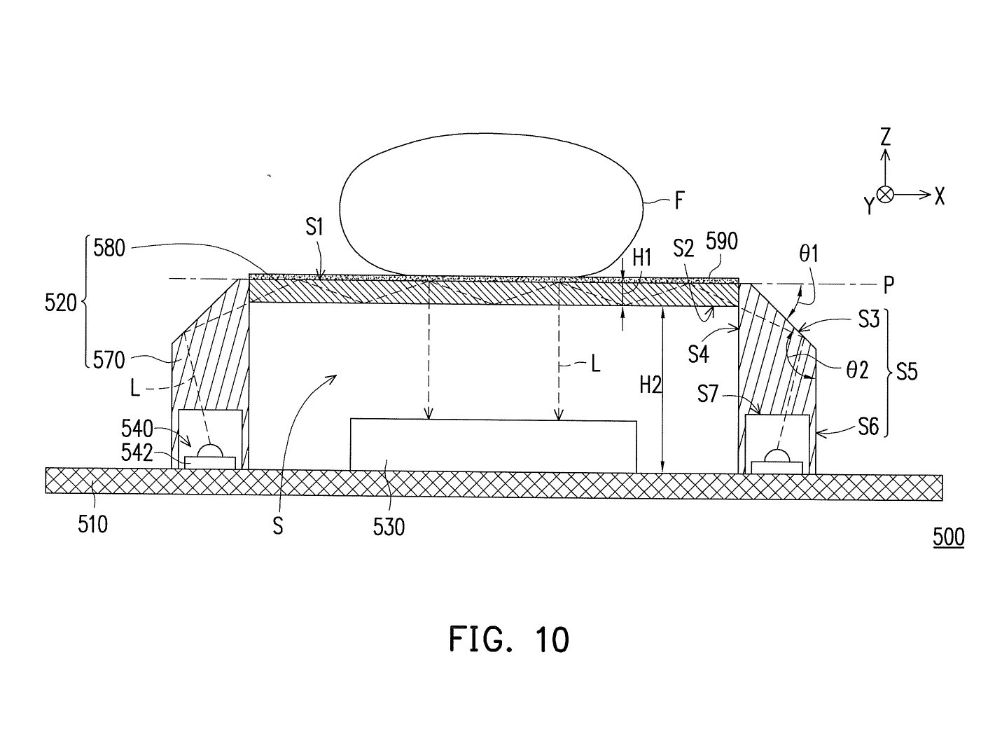

Referring to FIG. 10, FIG. 10 is a schematic cross-sectional view of an optical device 500 according to yet another embodiment of the invention. FIG. 10 shows a finger contacting the optical device 500. The embodiment of FIG. 10 is similar to the embodiment of FIG. 1 to FIG. 4. Similar elements will apply similar reference numerals as in the embodiment of FIG. 1 to FIG. 4. As seen in FIG. 10, the optical device 500 includes a substrate 510, a light emitting device 542, a light conductor 520, and an image capture unit 530. The light conductor 520 and the substrate 510 define a space S. The light conductor 520 includes a central portion 580 and a surrounding portion 570 connected to each other. The difference between the embodiment of FIG. 10 and the embodiment of FIG. 1 to FIG. 4 is that the optical device 500 further includes a microstructure layer 590 disposed on the first surface S 1. The microstructure layer 590 is adapted to increase light scattering, and the microstructure layer 590 can be, but not limited to, made of materials with particles by which the light can be scattered. In another example, the microstructure layer 590 has a rough surface regardless of what the material it is used. The rough surface also helps light scattering.

When the first surface S1 of the optical device 500 is not contacted by an object, the light enters the light conductor 520 and the microstructure layer 590. The light beams are scattered by the microstructure layer 590 and enter the light conductor 520. When the microstructure layer 590 of the first surface S1 of the optical device 500 is contacted by the finger F, part of the light beam is refracted into the finger F and is absorbed by the finger F. On the other hand, the valleys of the finger do not substantially contact the microstructure layer 590, and the light is still scattered by the microstructure layer 590 and refracted by the light conductor 120 to enter the image capture unit 530. Benefit from the microstructure layer 590, lights in the valley portions reflected to enter the image capture unit 530 are more than in the option device 100. Accordingly, the fingerprint image generated by the image capture unit 530 has darker ridge portions and brighter valley portions.

In other embodiments, the optical device 500 of FIG. 10 may be varied and modified as described in the embodiments of FIG. 1 to FIG. 9. The same will not be repeated herein.

To sum up, the light conductor surrounds the image capture unit, and reflects the light beam within the light conductor. Since a light conductor is thin, the optical device may be relatively thin, allowing convenient installation in devices with limited installation space. Accordingly, an electronic device installing the optical device can be relatively thin because the optical device does not increase the thickness of the electronic device.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. An optical device comprising:
an image capture unit;
at least one light emitting device; and
a light conductor, defining a space above a substrate on which the image capture unit is disposed, wherein the light conductor comprises:
a central portion, disposed above the space and comprising a first surface relatively far from the image capture unit and a second surface opposite to the first surface and relatively close to the image capture unit; and
a surrounding portion, connected to the central portion and surrounding the space, wherein the surrounding portion comprises a reflection surface connected to the first surface and tilted at an angle toward the image capture unit with respect to a plane of the first surface, wherein the reflection surface is adapted to perform total reflection.

2. The optical device as claimed in claim 1, wherein the surrounding portion comprises an inner surrounding surface enclosing the space, connected to the second surface of the central portion, and an outer surrounding surface being the reflection surface.

3. The optical device as claimed in claim 1, wherein the surrounding portion comprises an inner surrounding surface enclosing the space, connected to the second surface of the central portion, and an outer surrounding surface comprising at least two surfaces forming a obtuse angle, wherein one of the at least two surfaces is the reflection surface.

4. The optical device as claimed in claim 1, wherein the surrounding portion comprises an inner surrounding surface enclosing the space and comprising at least two surfaces forming a obtuse angle, wherein one of the at least two surfaces is connected to the second surface of the central portion, and an outer surrounding surface comprising at least two surfaces forming a obtuse angle, wherein one of the at least two surfaces is the reflection surface.

5. The optical device as claimed in claim 1, wherein the reflection surface is adapted to totally reflect light beams emitted from the at least one light emitting device to the first surface of the central portion.

6. The optical device as claimed in claim 1, wherein the reflection surface is tilted toward the image capture unit so as to form an obtuse angle with respect to the first surface.

7. The optical device as claimed in claim 1, wherein the surrounding portion of the light conductor defines at least one containing space adapted to enclose the at least one light emitting device.

8. The optical device as claimed in claim 1, wherein the surrounding portion of the light conductor further comprises a surface being an incident surface for the light beams from the at least one light emitting device.

9. The optical device as claimed in claim 1, wherein the reflection surface is coated with metal so as to totally reflect the light beams.

10. The optical device as claimed in claim 1, wherein the surrounding portion comprises an inner surrounding surface enclosing the space and connected to the second surface of the central portion, and the inner surrounding surface is coated with metal so as to totally reflect the light beams.

11. The optical device as claimed in claim 1, wherein the image capture unit is configured to capture an image of an object by receiving scattered light beams when total internal reflection at the first surface is frustrated by the object touching the optical device.

12. The optical device as claimed in claim 1, wherein the light conductor is light pervious to the light beam.

13. The optical device as claimed in claim 1, further comprising a microstructure layer, disposed on the first surface, wherein the microstructure layer is adapted to scatter light beams.
